(19) United States
(12) Patent Application Publication
(10) Pub. No.: US 2025/0220904 A1
(43) Pub. Date: Jul. 3, 2025

(54) SEMICONDUCTOR DEVICE

(71) Applicant: Samsung Electronics Co., Ltd., Suwon-si (KR)

(72) Inventors: Myunghun Woo, Suwon-si (KR); Kwangsoo Kim, Suwon-si (KR); Wanki Kim, Suwon-si (KR); Hakseon Kim, Suwon-si (KR); Daewon Ha, Suwon-si (KR)

(21) Appl. No.: 18/967,899

(22) Filed: Dec. 4, 2024

(30) Foreign Application Priority Data
Dec. 29, 2023 (KR) 10-2023-0197697

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

A semiconductor device includes a peripheral circuit structure and a cell structure that includes: gate electrodes extending in a first direction and spaced apart from each other in a second direction, where the gate electrodes define a channel hole extending in the second direction, a channel layer including a first region and a second region, a common source layer electrically connected to the second region of the channel layer, an upper insulating layer on the common source layer, where the upper insulating layer, the common source layer, and the second region of the channel layer define a back gate hole extending in the second direction, a back gate insulating layer on the channel hole and the back gate hole, and a back gate electrode that is in the channel hole and the back gate hole and is on the back gate insulating layer.

### CROSS-REFERENCE TO RELATED APPLICATION

This application is based on and claims priority under 35 U.S.C. § 119 to Korean Patent Application No. 10-2023-0197697, filed on Dec. 29, 2023, in the Korean Intellectual Property Office, the disclosure of which is incorporated by reference herein in its entirety.

### TECHNICAL FIELD

The present disclosure relates to a semiconductor device, and more specifically, to a semiconductor device having a memory string arranged in a vertical direction.

### BACKGROUND

Semiconductor devices capable of storing a large amount of data are desired in electronic systems requiring data storage. As a method of increasing the data storage capacity of semiconductor devices, a semiconductor device including three-dimensionally arranged memory cells instead of two-dimensionally arranged memory cells has been proposed. In addition, a semiconductor device has been proposed in which a portion of the semiconductor device is formed on a first substrate, another portion of the semiconductor device is formed on a second substrate, and the first substrate and the second substrate are bonded to each other.

### SUMMARY

The present disclosure provides a semiconductor device having excellent operation characteristics and improved integration.

The objective of the present disclosure is not limited to those mentioned above, and other objectives that are not mentioned will be clearly understood by those skilled in the art from the following description.

According to an aspect of the present disclosure, there is provided a semiconductor device including a peripheral circuit structure, and a cell structure on the peripheral circuit structure, where the cell structure includes: gate electrodes extending in a first direction and spaced apart from each other in a second direction intersecting the first direction, where the gate electrodes define a channel hole extending in the second direction, a channel layer including a first region in the channel hole and a second region extending from the first region in the second direction, a common source layer electrically connected to the second region of the channel layer, an upper insulating layer on the common source layer, where the upper insulating layer, the common source layer, and the second region of the channel layer define a back gate hole extending in the second direction, a back gate insulating layer on inner walls of the channel hole and inner walls of the back gate hole and extending in the second direction, and a back gate electrode that is in the channel hole and the back gate hole and is on the back gate insulating layer.

According to another aspect of the present disclosure, there is provided a semiconductor device including a peripheral circuit structure, and a cell structure on the peripheral circuit structure, where the cell structure includes: gate electrodes extending in a first direction and spaced apart from each other in a second direction intersecting the first direction, where the gate electrodes define a channel hole extending in the second direction, a channel layer including a first region in the channel hole and a second region extending from the first region in the second direction, a common source layer electrically connected to the second region of the channel layer, an upper insulating layer on the common source layer, where the upper insulating layer, the common source layer, and the second region of the channel layer define a back gate hole including a first back gate hole and a second back gate hole, the first back gate hole defined by a portion of the upper insulating layer and a first portion of the common source layer, and the second back gate hole defined by a second portion of the common source layer and the second region of the channel layer, a back gate insulating layer on inner walls of the channel hole and inner walls of the back gate hole and extending in the second direction, a back gate electrode that is in the channel hole and the back gate hole and is on the back gate insulating layer, and an insulating spacer on inner walls of the first back gate hole.

According to another aspect of the present disclosure, there is provided a semiconductor device including a peripheral circuit structure, and a cell structure on the peripheral circuit structure, where the cell structure includes: gate electrodes extending in a first direction and spaced apart from each other in a second direction intersecting the first direction, where the gate electrodes define a channel hole extending in the second direction, a channel structure including a back gate insulating layer, a back gate electrode, and a channel layer between the back gate insulating layer and the back gate electrode, the channel layer including a first region in the channel hole and a second region extending from the first region in the second direction, a common source layer electrically connected to the second region of the channel layer, an upper conductive layer on the common source layer, an upper insulating layer on the upper conductive layer, where the upper insulating layer, the common source layer, and the second region of the channel layer define a back gate hole including a first back gate hole and a second back gate hole, the first back gate hole defined by a portion of the upper insulating layer, a portion of the upper conductive layer, and a first portion of the common source layer, and the second back gate hole defined by a second portion of the common source layer and the second region of the channel layer, a back gate contact extending into the upper insulating layer and electrically connected to the back gate electrode, and a common source contact extending into the upper insulating layer and electrically connected to the common source layer, where the back gate insulating layer extends in the second direction and is on an inner wall of the back gate hole, and where the back gate electrode extends in the second direction, is on the back gate insulating layer, and is in the back gate hole.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to embodiments;

FIG. 2 is a circuit diagram of a memory block according to embodiments;

FIG. 3 is a perspective view of a representative configuration of a semiconductor device according to embodiments;

FIG. 4 is a plan layout view of a semiconductor device;

FIG. 5 is an enlarged layout view of region A of FIG. 4;

FIG. 6 is a cross-sectional view of the semiconductor device of FIG. 5, taken along line B-B′;

FIG. 7 is an enlarged view of region CX1 of FIG. 6;

FIG. 8 is a cross-sectional view of a semiconductor device according to embodiments;

FIG. 9 is an enlarged view of region CX2 of FIG. 8;

FIGS. 10, 11, 12, 13, 14, 15, 16, 17, 18, 19, 20, 21, and 22 are cross-sectional views illustrating a method of manufacturing a semiconductor device according to embodiments;

FIG. 23 is a schematic view of a data storage system including a semiconductor device according to embodiments;

FIG. 24 is a schematic perspective view of a data storage system including a semiconductor device according to embodiments; and

FIG. 25 is a schematic cross-sectional view of a semiconductor package according to embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection.

Hereinafter, embodiments are described in detail with reference to the accompanying drawings. The same reference numerals are used for the same components in the drawings, and repeated descriptions thereof are omitted.

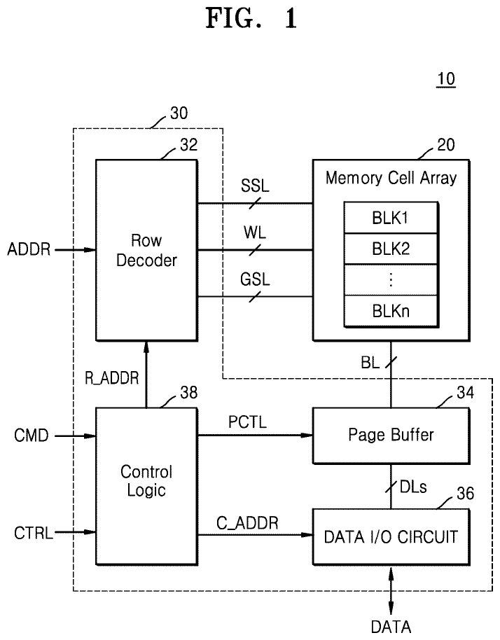

FIG. 1 is a block diagram of a semiconductor device 10 according to embodiments.

Referring to FIG. 1, the semiconductor device 10 may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through a bit line BL, a word line WL, a string select line SSL, and a ground select line GSL.

The peripheral circuit 30 may include a row decoder 32, a page buffer 34, a data input/output circuit 36, and a control logic 38. Although not shown in FIG. 1, the peripheral circuit 30 may further include an input/output interface, a column logic, a voltage generator, a pre-decoder, a temperature sensor, a command decoder, an address decoder, an amplifier circuit, etc.

The memory cell array 20 may be connected to the page buffer 34 through the bit line BL and may be connected to the row decoder 32 through the word line WL, the string select line SSL, and the ground select line GSL. In the memory cell array 20, each of the plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL, which are vertically stacked on a substrate.

The peripheral circuit 30 may receive an address ADDR, a command CMD, and a control signal CTRL from outside the semiconductor device 10 and may transmit and receive data DATA to and from a device outside the semiconductor device 10.

The row decoder 32 may select at least one of the plurality of memory cell blocks BLK1, BLK2, . . . , and BLKn in response to the address ADDR from the outside and may select the word line WL, the string select line SSL, and the ground select line GSL of the selected memory cell block. The row decoder 32 may transmit a voltage for performing a memory operation to the word line WL of the selected memory cell block.

The page buffer 34 may be connected to the memory cell array 20 through the bit line BL. In a program operation, the page buffer 34 may operate as a write driver to apply, to the bit line BL, a voltage according to the data DATA, which is to be stored in the memory cell array 20, and in a read operation, the page buffer 34 may operate as a sense amplifier to sense the data DATA stored in the memory cell array 20. The page buffer 34 may operate according to a control signal PCTL provided from the control logic 38.

The data input/output circuit 36 may be connected to the page buffer 34 through a plurality of data lines DLs. In a program operation, the data input/output circuit 36 may receive the data DATA from a memory controller (not shown) and may provide program data DATA to the page buffer 34, based on a column address C_ADDR provided from the control logic 38. In a read operation, the data input/output circuit 36 may provide read data DATA stored in the page buffer 34 to the memory controller based on the column address C_ADDR provided from the control logic 38.

The data input/output circuit 36 may transmit an address or a command, which is input thereto, to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data input/output circuit 36. The control logic 38 may generate various internal control signals that are used in the semiconductor device 10 in response to the control signal CTRL. For example, the control logic 38 may adjust a voltage level provided to the word line WL and the bit line BL in performing a memory operation, such as a program operation or an erase operation.

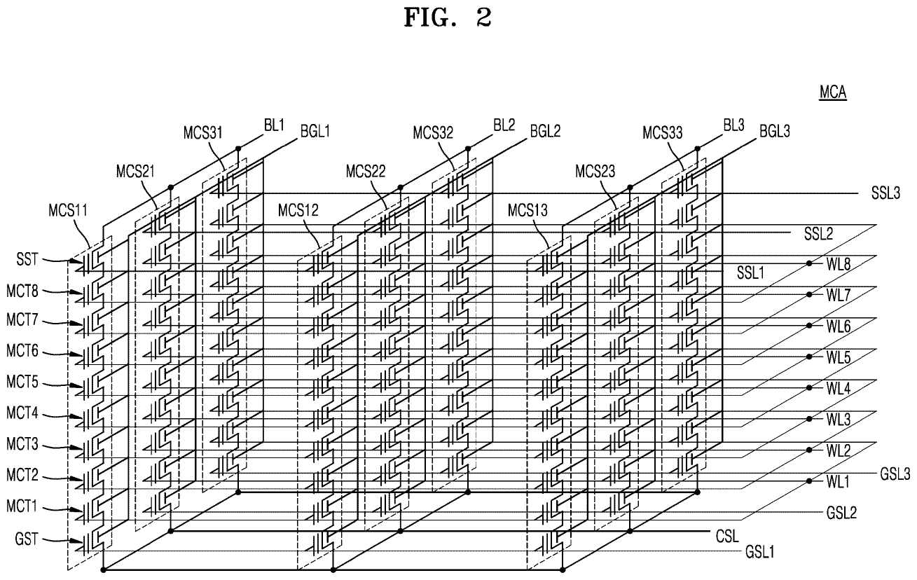

FIG. 2 is a circuit diagram of a memory cell block BLK according to embodiments.

Referring to FIG. 2, a memory cell array MCA may include memory cell strings MCS11, MCS12, MCS13, MCS21, MCS22, MCS23, MCS31, MCS32, MCS33, word lines WL1, WL2,

WL3, WL4, WL5, WL6, WL7, WL8, ground select lines GSL1, GSL2, GSL3, string select lines SSL1, SSL2, SSL3, and a common source line CSL.

The memory cell strings MCS11, MCS21, and MCS31 may be provided between a first bit line BL1, a first back gate line BGL1, and the common source line CSL, the memory cell strings MCS12, MCS22, and MCS32 may be provided between a second bit line BL2, a second back gate line BGL2, and the common source line CSL, and the memory cell strings MCS13, MCS23, and MCS33 may be provided between a third bit line BL3, a third back gate line BGL3, and the common source line CSL. Each of the memory cell strings (e.g., MCS11) may include a string select transistor SST, a plurality of memory cells MCT1 to MCT8, and a ground select transistor GST, which are connected in series to each other.

The string select transistor SST may be connected to the string select lines SSL1 to SSL3 corresponding thereto. The plurality of memory cells MCT1 to MCT8 may be respectively connected to the word lines WL1 to WL8 corresponding thereto. The ground select transistor GST may be connected to the ground select lines GSL1 to GSL3 corresponding thereto. The string select transistor SST may be connected to the first to third bit lines BL1 to BL3 corresponding thereto, and the ground select transistor GST may be connected to the common source line CSL.

In some embodiments, word lines (for example, WL1) provided at the same height may be connected in common to each other, the string select lines SSL1 to SSL3 may be separated from each other, and the ground select lines GSL1 to GSL3 may also be separated from each other. Although FIG. 2 shows that three string select lines SSL1 to SSL3 share word lines provided at the same height, the present disclosure is not limited thereto. For example, two string select lines may share word lines provided at the same height. As another example, four string select lines may share word lines provided at the same height.

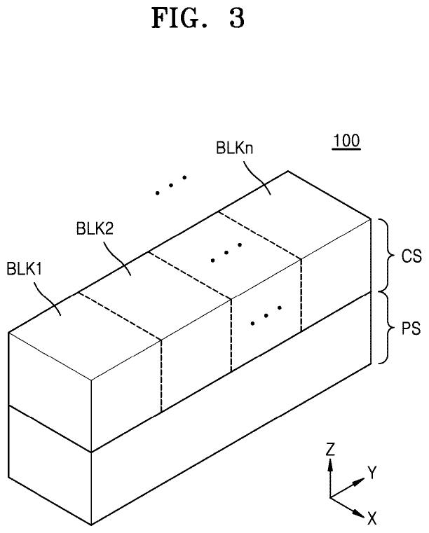

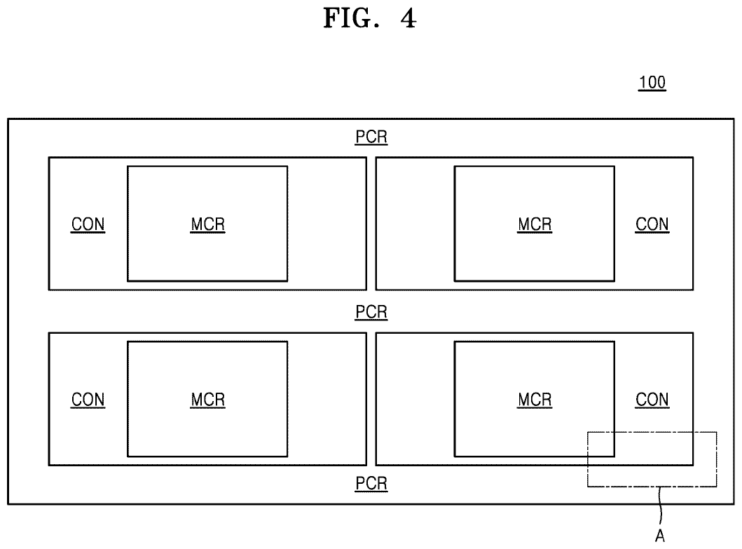

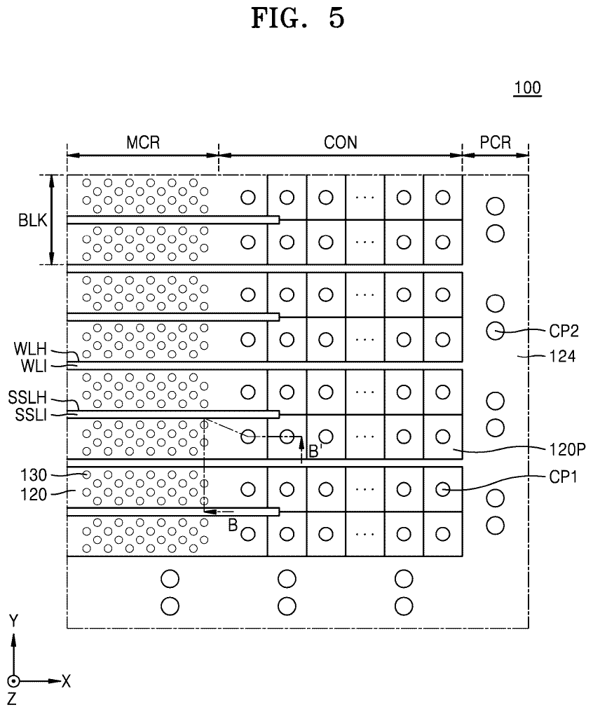

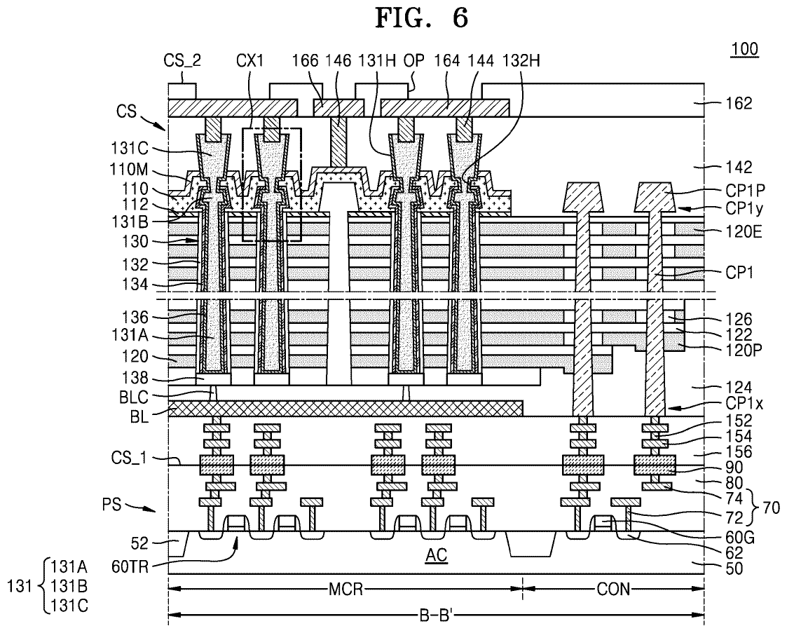

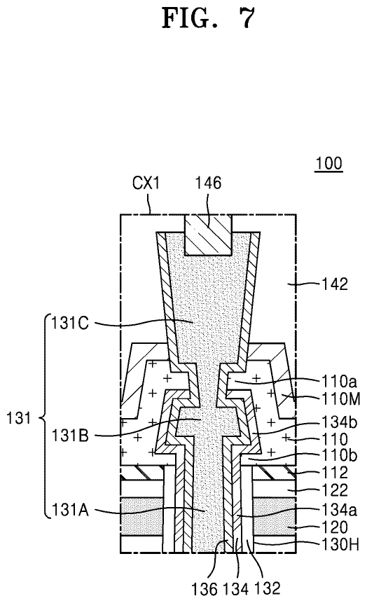

FIG. 3 is a perspective view of a representative configuration of a semiconductor device 100 according to embodiments. FIG. 4 is a plan layout view of the semiconductor device 100, and FIG. 5 is an enlarged layout view of region A of FIG. 4. FIG. 6 is a cross-sectional view of the semiconductor device 100 taken along line B-B′ of FIG. 5. FIG. 7 is an enlarged view of region CX1 of FIG. 6.

Referring to FIGS. 3 to 7, the semiconductor device 100 may include a cell structure CS and a peripheral circuit structure PS, which overlap each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, . . . , and BLKn. Each of the plurality of memory cell blocks BLK1, BLK2, . . . , and BLKn may include three-dimensionally arranged memory cells.

The peripheral circuit structure PS may include a peripheral circuit transistor 60TR and a peripheral circuit wiring structure 70, which are arranged on a substrate 50. An active region AC may be defined in the substrate 50 by a device separation layer 52, and a plurality of peripheral circuit transistors 60TR may be formed on the active region AC. Each of the plurality of peripheral circuit transistors 60TR may include a peripheral circuit gate 60G and a source/drain region 62 arranged in a portion of the substrate 50 on both sides of the peripheral circuit gate 60G.

The substrate 50 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium. The substrate 50 may be provided as a bulk wafer or an epitaxial layer. In some embodiments, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. An interlayer insulating layer 80 covering or overlapping the peripheral circuit transistor 60TR and the peripheral circuit wiring structure 70 may be arranged on the substrate 50. Each of the plurality of peripheral circuit wiring layers 74 may have a multilayer structure including a plurality of metal layers arranged at different vertical levels. A connection pad 90 may be arranged on the interlayer insulating layer 80, and the peripheral circuit structure PS and the cell structure CS may be electrically connected to and bonded to each other by the connection pad 90.

The cell structure CS may include a cell region MCR, a connection region CON, and a peripheral circuit connection region PCR. The cell region MCR may be a region in which a memory cell block BLK including a plurality of memory cell strings extending in the vertical direction Z is arranged. In the cell region MCR, a common source layer 110, a plurality of gate electrodes 120, and a channel structure 130 may be arranged. The channel structure 130 may penetrate or extend into the gate electrodes 120 and in the vertical direction Z, and the channel structure 130 may be connected to the common source layer 110. In the connection region CON, an extension portion 120E and a pad portion 120P, which are connected to the plurality of gate electrodes 120, and a first plug CP1 penetrating or extending into the extension portion 120E and the pad portion 120P and electrically connected to the pad portion 120P may be arranged. In the peripheral circuit connection region PCR, a second plug CP2 extending in the vertical direction Z and electrically connected to the peripheral circuit wiring structure 70 may be arranged.

The cell structure CS may include a first surface CS_1 connected to the peripheral circuit structure PS and a second surface CS_2 opposite to the first surface CS_1. FIG. 6 shows that the first surface CS_1 of the cell structure CS is arranged on a lower side of the cell structure CS, and the second surface CS_2 of the cell structure CS is arranged on an upper side of the cell structure CS. Herein, for convenience, as shown in FIG. 6, being arranged close to the first surface CS_1 of the cell structure CS is referred to as being arranged at a first vertical level, and being arranged close to the second surface CS_2 of the cell structure CS is referred to as being arranged at a second vertical level that is higher or greater than the first vertical level.

The gate electrodes 120 may be arranged apart from each other in the vertical direction Z in the cell region MCR, and the gate electrodes 120 may be alternately arranged with mold insulating layers 122. The gate electrodes 120 may extend into the connection region CON, and portions of the gate electrodes 120 arranged in the connection region CON may be referred to as extension portions 120E. Each of the extension portions 120E may have a horizontal length that gradually increases toward the second surface CS_2 of the cell structure CS (that is, in an upward direction in FIG. 6). Each of the extension portions 120E may have a step shape, and the pad portions 120P may be connected to ends of the extension portions 120E. Each of the pad portions 120P may have a greater thickness in the vertical direction Z than each of the extension portions 120E.

Each of the gate electrodes 120 may include a buried conductive layer and a conductive barrier layer at least partially surrounding a top surface, a bottom surface, and a side surface of the buried conductive layer. For example, the buried conductive layer may include a metal, such as tungsten, nickel, cobalt, or tantalum, a metal silicide, such as tungsten silicide, nickel silicide, cobalt silicide, or tantalum silicide, doped polysilicon, or a combination thereof. In some embodiments, the conductive barrier layer may include titanium nitride, tantalum nitride, tungsten nitride, or a combination thereof.

In some embodiments, the gate electrodes 120 may correspond to the ground select lines GSL1 to GSL3, the word lines WL1 to WL8, and at least one string select line SSL1 to SSL3, which form the memory cell strings MCS11 to MCS33 (see FIG. 2). For example, an uppermost one of the gate electrodes 120 may function as the ground select lines GSL1 to GSL3, two lowermost ones of the gate electrodes 120 may function as the string select lines SSL1 to SSL3, and the remaining ones of the gate electrodes 120 may function as the word lines WL1 to WL8. Accordingly, the memory cell strings MCS11 to MCS33, in which the ground select transistor GST, the string select transistor SST, and the memory cells MCT1 to MCT8 therebetween are connected in series, may be provided. In some embodiments, at least one of the gate electrodes 120 may function as a dummy word line, but the present disclosure is not limited thereto.

A stack separation insulating layer WLI may be arranged in a stack separation opening WLH penetrating or extending into the gate electrodes 120 and the mold insulating layers 122 and extending in the vertical direction Z. The stack separation insulating layer WLI may have a top surface arranged at a vertical level higher than the uppermost one of the gate electrodes 120 and may protrude or extend upward with respect to the uppermost one of the gate electrodes 120. In some embodiments, the gate electrodes 120 arranged between a pair of stack separation openings WLH may form one memory cell block BLK. In addition, in one memory cell block BLK, at least one gate electrode 120 (e.g., the lowermost one of the gate electrodes 120) may be separated into two gate electrodes 120 by a string separation opening SSLH. A string separation insulating layer SSLI may be arranged in the string separation opening SSLH.

A stack insulating layer 124 may be arranged to at least partially surround the gate electrodes 120, the extension portions 120E, and the pad portions 120P in the connection region CON and the peripheral circuit connection region PCR. In a plan view, the stack insulating layer 124 may be arranged to surround the gate electrodes 120 and may have a top surface arranged at the same level as the uppermost one of the gate electrodes 120 in the peripheral circuit connection region PCR.

The channel structure 130 may be arranged in a channel hole 130H penetrating or extending into the gate electrodes 120 and the mold insulating layers 122 and extending in the vertical direction. The channel structure 130 may include a gate insulating layer 132, a channel layer 134, a back gate insulating layer 136, a drain region 138, and a back gate electrode 131. The gate insulating layer 132, the channel layer 134, the back gate insulating layer 136, and the back gate electrode 131 may be sequentially arranged on an inner wall of the channel hole 130H.

In some embodiments, the back gate insulating layer 136 may protrude or extend in the vertical direction to cover or overlap an inner wall of a back gate hole. The back gate insulating layer 136 may cover or overlap an inner wall of the channel layer 134 in the channel hole 130H and may protrude or extend in the vertical direction to cover or overlap the inner wall of the back gate hole. In addition, the back gate electrode 131 may protrude or extend in the vertical direction to cover or overlap the back gate insulating layer 136 and fill or be in the back gate hole. The back gate electrode 131 may cover or overlap an inner wall of the back gate insulating layer 136 in the channel hole 130H and may protrude or extend in the vertical direction to cover or overlap the back gate insulating layer 136 in the back gate hole. The structures of the back gate insulating layer 136 and the back gate electrode 131 are described in detail below.

The drain region 138 electrically connected to the channel layer 134 may be arranged at one end of the channel structure 130. The drain region 138 may be connected to a bit line contact BLC, and the channel layer 134 may be electrically connected to a bit line BL through the drain region 138 and the bit line contact BLC.

In some embodiments, the channel layer 134 may include a first region 134a and a second region 134b. The first region 134a of the channel layer 134 may refer to a region arranged in the channel hole 130H, and the second region 134b of the channel layer 134 may refer to a region connected to the first region 134a and arranged at a higher vertical level than an etch stop layer 112. For example, the first region 134a may refer to a portion of the channel layer 134 that is arranged at the same vertical level as the gate electrode 120 and at least partially surrounded by the gate electrode 120. In this case, a horizontal width of the second region 134b may be greater than a horizontal width of the first region 134a.

A side surface and a top surface of the channel layer 134 may not be covered or overlapped by the gate insulating layer 132 in the second region 134b. The common source layer 110 may be connected to portions of the side surface and the top surface of the channel layer 134 in the second region 134b. A portion of the top surface of the channel layer 134 may be penetrated by or extended into by the back gate hole in the second region 134b.

In some embodiments, the back gate hole may include a first back gate hole 131H and a second back gate hole 132H. The first back gate hole 131H may penetrate or extend into portions of an upper insulating layer 142 and the common source layer 110. The second back gate hole 132H may be arranged in a bottom of the first back gate hole 131H. The second back gate hole 132H may penetrate or extend into the common source layer 110 and a top surface of the second region 134b of the channel layer 134. In this case, a horizontal width of the first back gate hole 131H may be greater than a horizontal width of the second back gate hole 132H.

In some embodiments, the back gate insulating layer 136 may be arranged on the inner walls of the channel hole 130H and the back gate hole and may extend in the vertical direction. The back gate insulating layer 136 may cover or overlap the inner wall of the channel layer 134. In detail, the back gate insulating layer 136 may be arranged in the first region 134a and the second region 134b of the channel layer 134. The back gate insulating layer 136 may be arranged on inner walls of the first back gate hole 131H and the second back gate hole 132H. The back gate insulating layer 136 arranged in the channel hole 130H and the back gate hole may be formed as a single body. In some embodiments, the back gate insulating layer 136 may include silicon oxide, hafnium oxide, aluminum oxide, zirconium oxide, tantalum oxide, etc.

In some embodiments, the back gate electrode 131 may cover or overlap the back gate insulating layer 136 to fill or be in the channel hole 130H and the back gate hole. The back gate electrode 131 may extend in the vertical direction Z in the channel hole 130H and the back gate hole. The back gate insulating layer 136 may be arranged on a sidewall of the back gate electrode 131. The back gate electrode 131 may be electrically insulated from the channel layer 134 and the common source layer 110 by the back gate insulating layer 136 arranged between the back gate electrode 131 and each of the channel layer 134 and the common source layer 110.

A bottom surface of the back gate electrode 131 may be covered or overlapped by the back gate insulating layer 136 at one end of the channel structure 130, and the back gate insulating layer 136 may be arranged between the bottom surface of the back gate electrode 131 and the drain region 138. A top surface of the back gate electrode 131 may not be covered or overlapped by the back gate insulating layer 136, and a back gate contact 144 may be arranged on the top surface of the back gate electrode 131.

In some embodiments, the back gate electrode 131 may include a first portion 131A, a second portion 131B, and a third portion 131C. The first portion 131A may be arranged in the first region 134a of the channel layer 134. The first portion 131A of the back gate electrode 131 may have a shape of which a width increases toward the peripheral circuit structure PS.

The second portion 131B may be connected to the first portion 131A in the vertical direction and may be arranged in the second region 134b of the channel layer 134. In some embodiments, a horizontal width of the second portion 131B may be greater than a horizontal width of the first portion 131A.

The third portion 131C may be connected to the second portion 131B in the vertical direction and may be arranged in the back gate hole. In some embodiments, the third portion 131C of the back gate electrode 131 may have a shape of which a horizontal width increases away from the peripheral circuit structure PS in the vertical direction. In this case, a horizontal width of the back gate electrode 131 arranged in the first back gate hole 131H may be greater than a horizontal width of the back gate electrode 131 arranged in the second back gate hole 132H.

In some embodiments, the first portion 131A, the second portion 131B, and the third portion 131C of the back gate electrode 131 may include the same material. In addition, the first portion 131A, the second portion 131B, and the third portion 131C may be formed as a single body (e.g., the first portion 131A, the second portion 131B, and the third portion 131C of the back gate electrode 131 are unitary). For example, the back gate electrode 131 may include a doped polysilicon layer, but the present disclosure is not limited thereto. When data write operations, read operations, or erase operations of the memory cells MCT1 to MCT8 (see FIG. 2) are performed, a certain voltage (or signal) may ”e ap'lied to the back gate electrode 131 through the first to third back gate lines BGL1 to BGL3 (see FIG. 2).

The gate insulating layer 132 may have a structure including a tunneling dielectric layer, a charge storage layer, and a blocking dielectric layer sequentially on an outer wall of the channel layer 134.

The tunneling dielectric layer may include silicon oxide, hafnium oxide, aluminum oxide, zirconium oxide, tantalum oxide, etc. The charge storage layer may be a region in which electrons having passed through the tunneling dielectric layer from the channel layer 134 are stored and may include silicon nitride, boron nitride, silicon boron nitride, or impurity-doped polysilicon. The blocking dielectric layer may include silicon oxide, silicon nitride, or a metal oxide having a higher dielectric constant than silicon oxide. The metal oxide may include hafnium oxide, aluminum oxide, zirconium oxide, tantalum oxide, or a combination thereof.

In some embodiments, the gate insulating layer 132 may include a ferroelectric dielectric material. For example, the charge storage layer may include a metal oxide having ferroelectric material properties. For example, the charge storage layer may include a ferroelectric material capable of storing data through hysteresis behavior caused by a voltage applied to the charge storage layer. In some embodiments, the charge storage layer may include at least one of hafnium oxide, zirconium oxide, and hafnium zirconium oxide.

The etch stop layer 112 may be arranged on the uppermost one of the gate electrodes 120, and the etch stop layer 112 may include polysilicon. In some embodiments, the etch stop layer 112 may be omitted.

The common source layer 110 may be connected to the second region 134b of the channel layer 134 on the etch stop layer 112 and may be conformally formed to cover or overlap a top surface of the stack separation insulating layer WLI. In a plan view, the common source layer 110 may be arranged over the entire cell region MCR.

In some embodiments, the common source layer 110 may cover or overlap portions of the top surface and the side surface of the channel layer 134. In addition, the common source layer 110 may cover or overlap a portion of a side surface of the back gate insulating layer 136. Because the first back gate hole 131H penetrates or extends into a portion of the common source layer 110 and the second back gate hole 132H penetrates or extends into the common source layer 110, the common source layer 110 may include a first protrusion 110a. In a plan view, the first protrusion 110a may have a shape protruding horizontally toward the second back gate hole 132H.

In some embodiments, the common source layer 110 may cover or overlap portions of the top surface and the side surface of the channel layer 134. In addition, the common source layer 110 may cover or overlap a top surface of the gate insulating layer 132. Because the second region 134b of the channel layer 134 is arranged to protrude or extend from the etch stop layer 112, the common source layer 110 may include a second protrusion 110b. In a plan view, the second protrusion 110b may have a shape protruding horizontally toward the channel layer 134. Because the common source layer 110 includes the first protrusion 110a and the second protrusion 110b, a sufficient contact area may be secured between the common source layer 110 and the channel layer 134.

In some embodiments, an upper conductive layer 110M may be arranged on a top surface of the common source layer 110. The upper conductive layer 110M may include a metal oxide, such as titanium nitride, tantalum nitride, or tungsten nitride, a metal, such as tungsten, molybdenum, chromium, nickel, cobalt, or tantalum, a metal silicide, such as tungsten silicide, nickel silicide, cobalt silicide, or tantalum silicide, or a combination thereof. In some embodiments, the upper conductive layer 110M may be formed in a stacked structure including two or more layers of different materials. In this case, the first back gate hole 131H may penetrate or extend into portions of the upper insulating layer 142, the upper conductive layer 110M, and the common source layer 110 and may extend in the vertical direction Z.

In some embodiments, a first end CP1x of the first plug CP1 may be arranged adjacent to the peripheral circuit structure PS, and a second end CP1y of the first plug CP1 may be arranged opposite to the first end CP1x. The first plug CP1 may have an inclined sidewall such that a width of the first end CP1x is greater than a width of the second end CP1y.

In some embodiments, the first plug CP1 may include a metal, such as tungsten, nickel, cobalt, or tantalum, a metal nitride, such as titanium nitride, tantalum nitride, or tungsten nitride, a metal silicide, such as tungsten silicide, nickel silicide, cobalt silicide, or tantalum silicide, doped polysilicon, or a combination thereof.

In the peripheral circuit connection region PCR, the second plug CP2 may be arranged to penetrate or extend into the stack insulating layer 124. A shape and a constituent material of the second plug CP2 may be similar to those of the first plug CP1.

A connection via 152, a connection wiring layer 154, and an interlayer insulating layer 156 at least partially surrounding the connection via 152 and the connection wiring layer 154 may be arranged between the stack insulating layer 124 and the peripheral circuit structure PS. Each of the connection via 152 and the connection wiring layer 154 may be formed as multiple layers so as to be arranged at multiple vertical levels, and may electrically connect the bit line BL, the first plug CP1, and the second plug CP2 to the peripheral circuit structure PS through the connection pad 90.

The upper insulating layer 142 may be arranged on the upper conductive layer 110M. The upper insulating layer 142 may have a flat top surface throughout the cell region MCR and the connection region CON. The upper insulating layer 142 may be arranged to cover or overlap a top surface of the upper conductive layer 110M and a top surface of the first plug CP1.

The back gate contact 144 may penetrate or extend into the upper insulating layer 142. The back gate contact 144 may be arranged at a position vertically overlapping each channel structure 130. For example, as shown in FIG. 6, the back gate contact 144 may be arranged to be offset in a first horizontal direction X and a second horizontal direction Y. In some embodiments, a spacer at least partially surrounding a sidewall of the back gate contact 144 may be further included. An end of the back gate contact 144 may be at least partially surrounded by the back gate electrode 131. For example, the third portion 131C of the back gate electrode 131 may at least partially surround the back gate contact 144. A top surface of the back gate contact 144 may be arranged at the same vertical level as a top surface of the upper insulating layer 142.

A common source contact 146 may penetrate or extend into the upper insulating layer 142. The common source contact 146 may penetrate or extend into the upper insulating layer 142 but may not penetrate or extend into the upper conductive layer 110M and the common source layer 110. The common source contact 146 may be arranged at a position vertically overlapping the stack separation opening WLH or the stack separation insulating layer WLI. For example, as shown in FIG. 6, the common source contacts 146 may be arranged in a line in the first horizontal direction X. In some embodiments, a spacer at least partially surrounding a sidewall of the common source contact 146 may be further included. A top surface of the common source contact 146 may be arranged at the same vertical level as the top surface of the upper insulating layer 142.

In some embodiments, each of the back gate contact 144 and the common source contact 146 may include a metal, such as tungsten, nickel, cobalt, or tantalum, a metal nitride, such as titanium nitride, tantalum nitride, or tungsten nitride, a metal silicide, such as tungsten silicide, nickel silicide, cobalt silicide, or tantalum silicide, or a combination thereof.

A first rear wiring layer 164 and a second rear wiring layer 166 may be arranged on the upper insulating layer 142. The first rear wiring layer 164 may be electrically connected to the back gate contact 144, and the second rear wiring layer 166 may be arranged apart from the first rear wiring layer 164 in a horizontal direction and may be electrically connected to the common source contact 146. For example, as shown in FIG. 6, the second rear wiring layer 166 may be arranged at a position vertically overlapping the stack separation opening WLH and may be electrically connected to the common source layer 110 through the common source contact 146. The first rear wiring layer 164 may be arranged in a region between two stack separation openings WLH adjacent to each other, that is, at a position vertically overlapping the channel structure 130. The first rear wiring layer 164 may be commonly and electrically connected to the back gate electrodes 131 of a plurality of channel structures 130 arranged between two stack separation openings WLH adjacent to each other (or between two stack separation insulating layers WLI adjacent to each other).

A passivation layer 162 may be arranged on the first rear wiring layer 164 and the second rear wiring layer 166, and an opening OP of the passivation layer 162 may be arranged to expose at least one of a portion of a top surface of the first rear wiring layer 164 and a portion of a top surface of the second rear wiring layer 166. The first rear wiring layer 164 may be configured to apply a back gate voltage from an external connection terminal to the back gate electrode 131 in the channel structure 130 through the back gate contact 144, and/or the first rear wiring layer 164 may be electrically connected to the peripheral circuit structure PS through the second plug CP2 (see FIG. 5). The second rear wiring layer 166 may be configured to apply a common source voltage from an external connection terminal to the common source layer 110 through the common source contact 146, and/or the second rear wiring layer 166 may be electrically connected to the peripheral circuit structure PS through the second plug CP2 (see FIG. 5).

According to embodiments, the back gate electrode 131 may be included in the channel structure 130. For example, when the back gate electrode 131 is included in the channel structure 130, for a programming operation, a back gate voltage may be applied to the back gate electrode 131, a programming voltage may be applied to a selected word line, and a relatively low (e.g., 0 V) pass voltage may be applied to an unselected word line. Accordingly, in a semiconductor device according to a comparative example, in which a relatively high pass voltage is applied to an unselected word line, a disturb phenomenon in which data is stored in an unselected memory cell may be prevented or reduced.

In addition, because a process of forming the back gate electrode 131 is performed after bonding the peripheral circuit structure PS to the cell structure CS, the risk of defects occurring in the back gate electrode 131 during the bonding process may be eliminated or reduced.

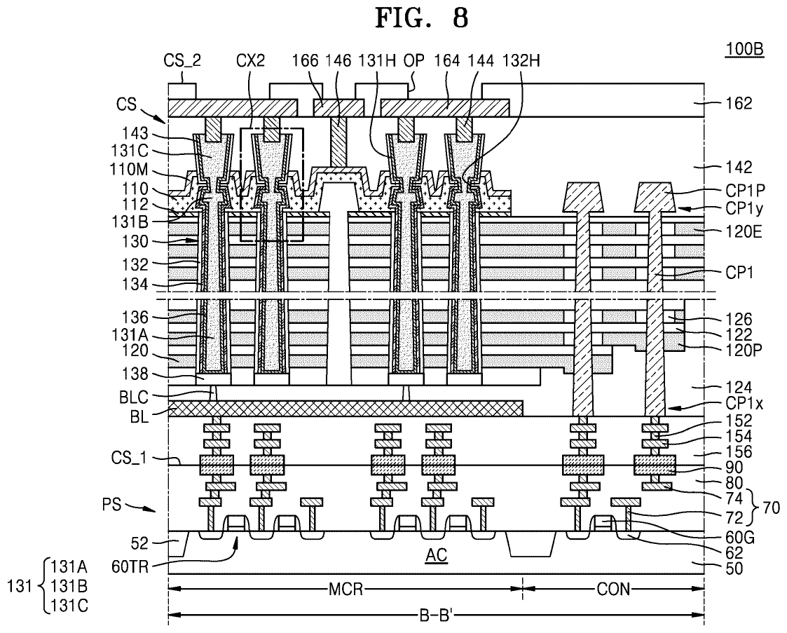

FIG. 8 is a cross-sectional view of a semiconductor device 100B according to embodiments.

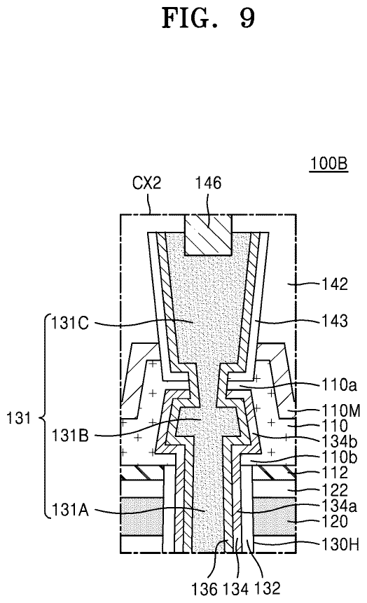

FIG. 9 is an enlarged view of region CX2 of FIG. 8.

In the configuration of the semiconductor device 100B of FIGS. 8 and 9, the same reference numerals as those of the semiconductor device 100 of FIGS. 1 to 7 denote the same components. Accordingly, the semiconductor device 100B of FIGS. 8 and 9 is described focusing on differences from the semiconductor device 100 of FIGS. 1 to 7.

In some embodiments, the semiconductor device 100B of the present disclosure may further include an insulating spacer 143. The insulating spacer 143 may cover or overlap an inner wall of the first back gate hole 131H. In detail, the insulating spacer 143 may cover or overlap portions of a sidewall and a bottom surface of the first back gate hole 131H. The insulating spacer 143 may be arranged between the back gate insulating layer 136 and the upper insulating layer 142. In this case, the insulating spacer 143 may include at least one of silicon nitride, silicon oxide, and silicon oxynitride.

In some embodiments, the insulating spacer 143 may be arranged on a portion of the first protrusion 110a of the common source layer 110. Because the insulating spacer 143 is arranged on the portion of the first protrusion 110a, insulation performance between the back gate electrode 131 and the common source layer 110 may be improved. Because the back gate insulating layer 136 and the insulating spacer 143 are arranged in a double-layer structure between the back gate electrode 131 and the common source layer 110, breakdown voltage performance between the back gate electrode 131 and the common source layer 110 may be improved. In addition, because the insulating spacer 143 is arranged around the second back gate hole 132H, which is relatively thin, structural stability may be improved.

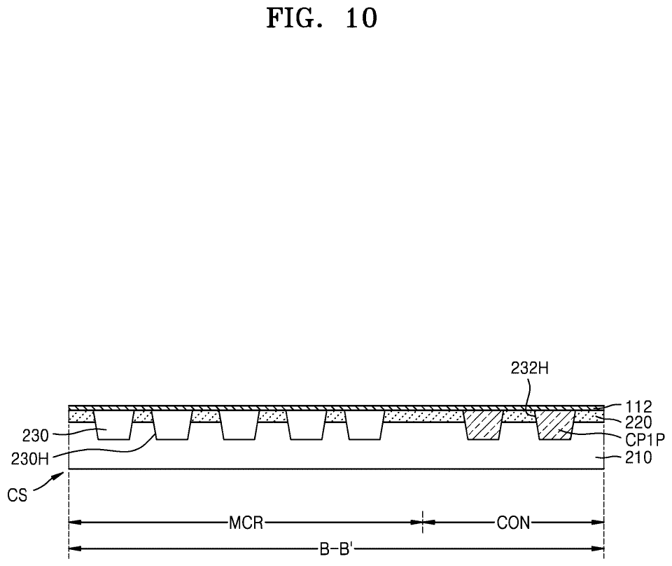

FIGS. 10 to 22 are cross-sectional views illustrating a method of manufacturing the semiconductor device 100, according to embodiments.

Referring to FIG. 10, a buffer insulating layer 220 may be formed on a cell substrate 210, and portions of the cell substrate 210 and the buffer insulating layer 220 may be removed to form an opening 230H and a landing pad opening 232H. Thereafter, a sacrificial layer 230 may be formed in the opening 230H, and a landing pad portion CP1P may be formed in the landing pad opening 232H.

In some embodiments, each of the sacrificial layer 230 and the landing pad portion CP1P may be formed using a metal, such as tungsten, nickel, cobalt, or tantalum, a metal nitride, such as titanium nitride, tantalum nitride, or tungsten nitride, a metal silicide, such as tungsten silicide, nickel silicide, cobalt silicide, or tantalum silicide, or a combination thereof. In some embodiments, the sacrificial layer 230 and the landing pad portion CP1P may be formed using the same material, but in other embodiments, the sacrificial layer 230 and the landing pad portion CP1P may be formed using different materials.

Thereafter, the etch stop layer 112 covering or overlapping the sacrificial layer 230 and the landing pad portion CP1P may be formed on the buffer insulating layer 220.

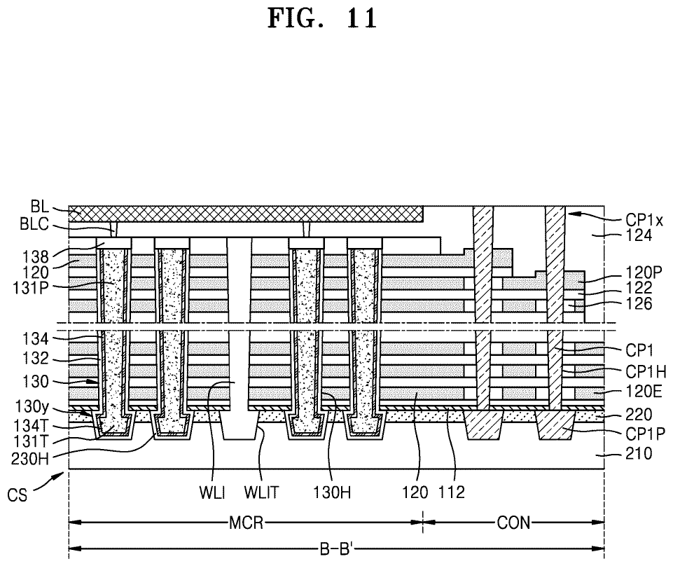

Referring to FIG. 11, the gate electrodes 120 and the mold insulating layers 122 may be alternately formed in the cell region MCR and the connection region CON, and the extension portions 120E and the pad portion 120P connected to the gate electrodes 120 may be formed in the connection region CON. In addition, the channel structure 130 penetrating or extending into the gate electrodes 120 and extending in the vertical direction Z and the bit line BL connected to the channel structure 130 may be formed in the cell region MCR.

In some embodiments, in the process of forming the channel structure 130, a mold stack alternately including sacrificial layers (not shown) and the mold insulating layers 122 may be formed on the etch stop layer 112 in the cell region MCR and the connection region CON, and the channel hole 130H penetrating or extending into the mold stack may be formed in the cell region MCR. The channel hole 130H may be formed to penetrate or extend into the etch stop layer 112 and expose a top surface of the sacrificial layer 230 (see FIG. 10) arranged in the opening 230H.

Thereafter, the sacrificial layer 230 may be removed, the gate insulating layer 132, the channel layer 134, and a channel insulating layer 131P may be sequentially formed on an inner wall of the channel hole 130H and an inner wall of the opening 230H, and the drain region 138 may be formed at an entrance of the channel hole 130H.

In some embodiments, the opening 230H may be formed to have a greater horizontal width than the channel hole 130H, and accordingly, a portion of the channel insulating layer 131P arranged in the opening 230H may be formed to have a greater horizontal width than a portion of the channel insulating layer 131P arranged in the channel hole 130H. Herein, the portion of the channel insulating layer 131P arranged in the opening 230H of the channel hole 130H is referred to as an extension portion 131T.

In addition, the first plug CP1 penetrating or extending into the extension portions 120E and the pad portion 120P may be formed in the connection region CON. In some embodiments, a first plug hole CP1H penetrating or extending into the mold stack may be formed in the connection region CON. A top surface of the landing pad portion CP1P may be exposed to a bottom of the first plug hole CP1H. Thereafter, a portion of the sacrificial layer 230 exposed to a sidewall of the first plug hole CP1H may be removed by lateral etching, and an insulating pattern 126 may be formed in a region from which the sacrificial layer 230 has been removed. Thereafter, the first plug CP1 may be formed in the first plug hole CP1H.

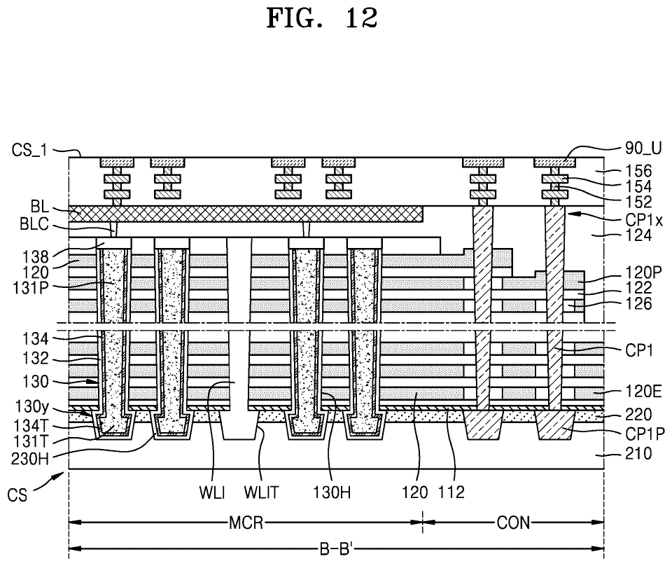

Referring to FIG. 12, the connection via 152 and the connection wiring layer 154, which are electrically connected to the bit line BL and the first plug CP1, and the interlayer insulating layer 156 may be formed. A connection pad 90_U may be formed on a top surface of the interlayer insulating layer 156.

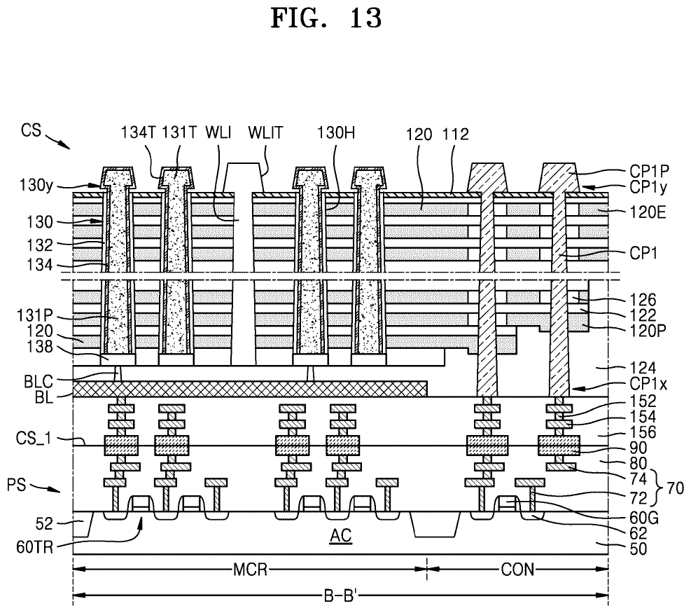

Referring to FIG. 13, the peripheral circuit structure PS may be prepared. The peripheral circuit structure PS may include the peripheral circuit transistor 60TR and the peripheral circuit wiring structure 70, which are arranged on the substrate 50. The active region AC may be defined in the substrate 50 by the device separation layer 52, and the plurality of peripheral circuit transistors 60TR may be formed on the active region AC. Each of the plurality of peripheral circuit transistors 60TR may include the peripheral circuit gate 60G and the source/drain region 62 arranged in a portion of the substrate 50 on both sides of the peripheral circuit gate 60G.

Thereafter, the peripheral circuit structure PS may be attached to the cell structure CS. The peripheral circuit structure PS and the cell structure CS may be attached to each other by using a metal-oxide hybrid bonding method through the connection pad 90 and the interlayer insulating layers 80 and 156, but the present disclosure is not limited thereto.

Thereafter, the structure in which the peripheral circuit structure PS and the cell structure CS are attached to each other may be turned over such that the cell substrate 210 (see FIG. 12) faces upward, and the cell substrate 210 may be removed. The cell substrate 210 may be removed through a grinding process and a subsequent etching process, and in this case, the buffer insulating layer 220 (see FIG. 12) may be exposed.

Thereafter, the buffer insulating layer 220 may also be removed, and a top surface of the etch stop layer 112 may be exposed. As the buffer insulating layer 220 is removed, a protruding region 130y of the channel structure 130 and the second end CP1y of the first plug CP1 may protrude or extend onto the top surface of the etch stop layer 112. As the cell substrate 210 and the buffer insulating layer 220 are removed, an upper side of the stack separation insulating layer WLI may also be exposed and protrude or extend above the etch stop layer 112.

A portion of the gate insulating layer 132 exposed to the protruding region 130y of the channel structure 130 may be removed to expose the second region 134b of the channel layer 134. The process of removing the gate insulating layer 132 may be performed until the top surface of the etch stop layer 112 is exposed.

In some embodiments, the gate insulating layer 132 may be arranged at a lower level than the second region 134b of the channel layer 134, and an upper side of the gate insulating layer 132 may be removed so that portions of a top surface and of a sidewall of the channel layer 134 are exposed. The gate insulating layer 132 may be removed, and the second region 134b of the channel layer 134 may be exposed at a vertical level higher than the etch stop layer 112.

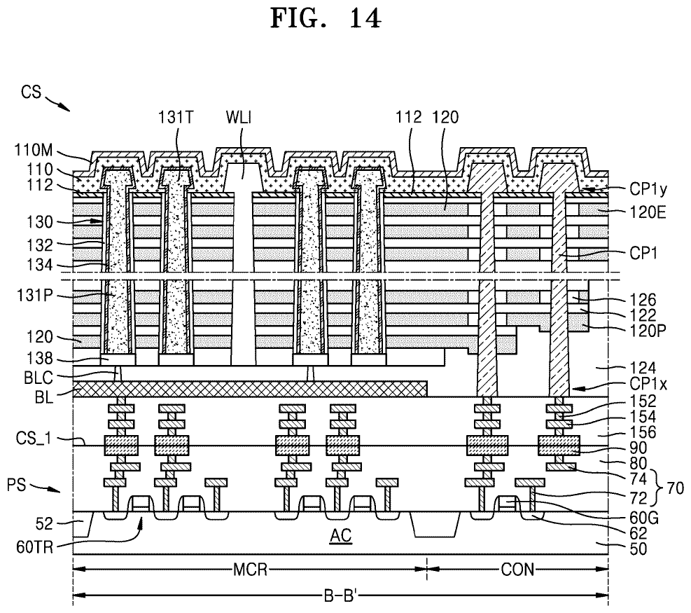

Referring to FIG. 14, the common source layer 110 may be formed in the cell region MCR, the connection region CON, and the peripheral circuit connection region PCR. The common source layer 110 may be formed using polysilicon. For example, the common source layer 110 may be formed using polysilicon doped with n-type impurities. In the cell region MCR, the common source layer 110 may be conformally formed on the exposed top surfaces of the etch stop layer 112 and the channel layer 134. In the connection region CON, the common source layer 110 may cover or overlap the second end CP1y of the first plug CP1.

In some embodiments, the upper conductive layer 110M may be formed on a top surface of the common source layer 110. The upper conductive layer 110M may include a metal oxide, such as titanium nitride, tantalum nitride, or tungsten nitride, a metal, such as tungsten, molybdenum, chromium, nickel, cobalt, or tantalum, a metal silicide, such as tungsten silicide, nickel silicide, cobalt silicide, or tantalum silicide, or a combination thereof. In some embodiments, the upper conductive layer 110M may be formed in a stacked structure including two or more layers of different materials.

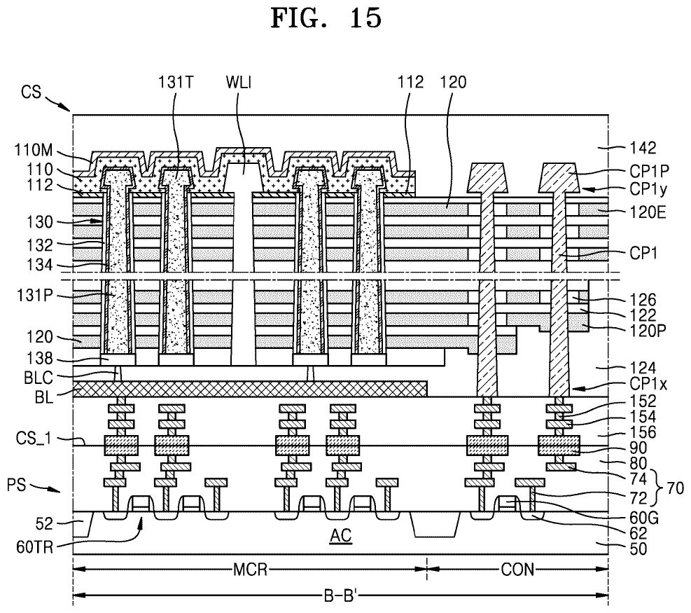

Referring to FIG. 15, a portion of the common source layer 110, a portion of the upper conductive layer 110M, and a portion of the etch stop layer 112, which are arranged in the connection region CON and the peripheral circuit connection region PCR, may be removed.

In some embodiments, a mask pattern may be formed on the upper conductive layer 110M in the cell region MCR, and by using the mask pattern as an etch mask, the portions of the common source layer 110, the upper conductive layer 110M, and the etch stop layer 112, which are arranged in the connection region CON and the peripheral circuit connection region PCR, may be removed. As the common source layer 110, the upper conductive layer 110M, and the etch stop layer 112 arranged in the connection region CON and the peripheral circuit connection region PCR are removed, the second end CP1y of the first plug CP1 and an uppermost one of the mold insulating layers 122 may be exposed again.

Thereafter, in the cell region MCR, the connection region CON, and the peripheral circuit connection region PCR, the upper insulating layer 142 may be formed on the upper conductive layer 110M and the uppermost one of the mold insulating layers 122. The upper insulating layer 142 may be formed to a sufficiently large height so that the upper insulating layer 142 covers or overlaps both the upper conductive layer 110M and the second end CP1y of the first plug CP1 and has a flat top level or surface.

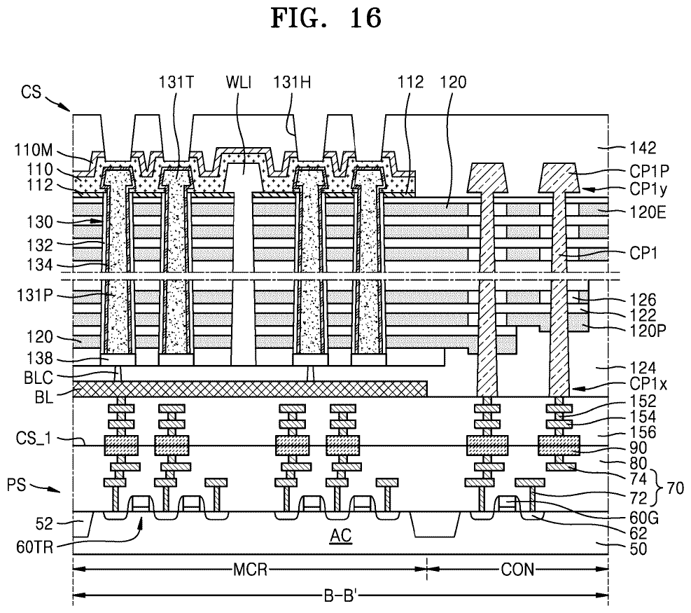

Referring to FIG. 16, a mask pattern may be formed on the upper insulating layer 142, and by using the mask pattern as an etch mask, a portion of the upper insulating layer 142, a portion of the upper conductive layer 110M, and a portion of the common source layer 110 may be removed to form the first back gate hole 131H.

In some embodiments, the first back gate hole 131H may be formed at a position overlapping the channel structure 130 in the vertical direction. In the process of forming the first back gate hole 131H, a portion of the upper conductive layer 110M and a portion of the common source layer 110 may be removed so that a portion of the upper conductive layer 110M and a portion of the common source layer 110 are exposed.

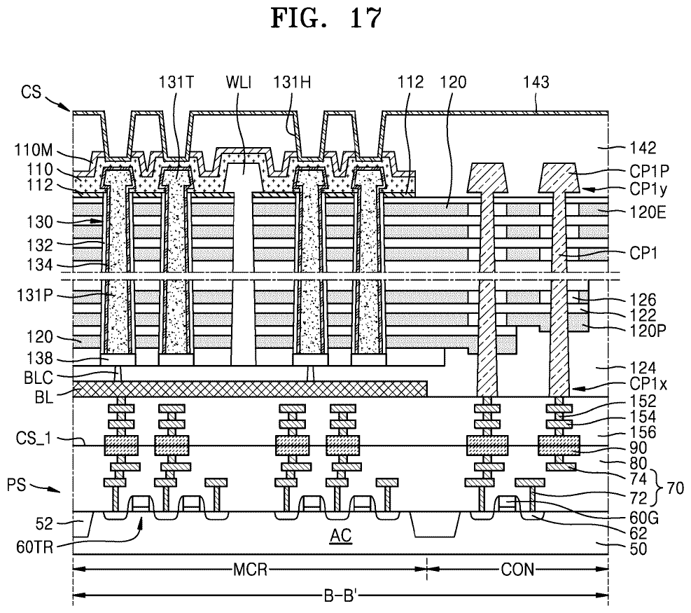

Referring to FIG. 17, the insulating spacer 143 covering or overlapping a sidewall of the first back gate hole 131H and a top surface of the upper insulating layer 142 may be formed. The insulating spacer 143 may conformally cover or overlap the first back gate hole 131H and the upper insulating layer 142. The insulating spacer 143 may be formed to cover or overlap the exposed portion of the upper conductive layer 110M and the exposed portion of the common source layer 110.

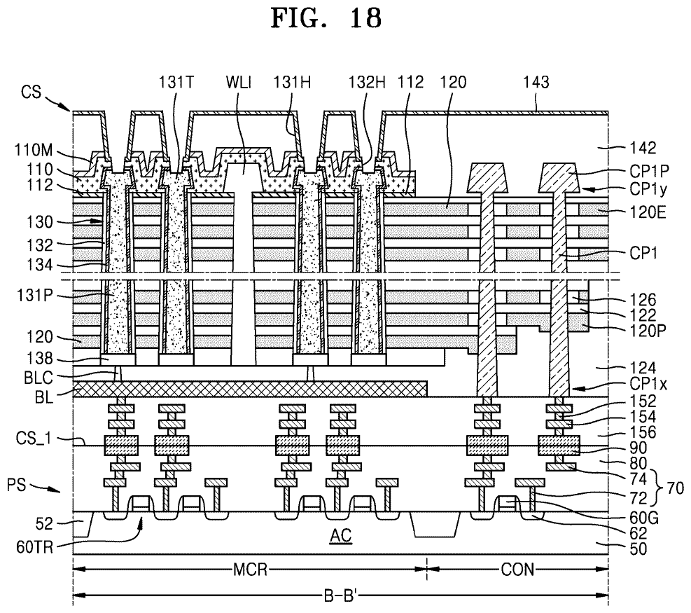

Referring to FIG. 18, a portion of the insulating spacer 143 covering or overlapping a bottom of the first back gate hole 131H may be removed to form the second back gate hole 132H. In the process of forming the second back gate hole 132H, a portion of the common source layer 110, a portion of the channel layer 134, and a portion of the channel insulating layer 131P may be removed. A portion of the second region 134b of the channel layer 134 arranged in the protruding region 130y of the channel structure 130 may be removed, and a top surface of the extension portion 131T of the channel insulating layer 131P may be exposed.

In some embodiments, in the process of forming the first back gate hole 131H and the second back gate hole 132H in FIGS. 16 to 18, the first protrusion 110a of the common source layer 110, which has been described above, may be formed.

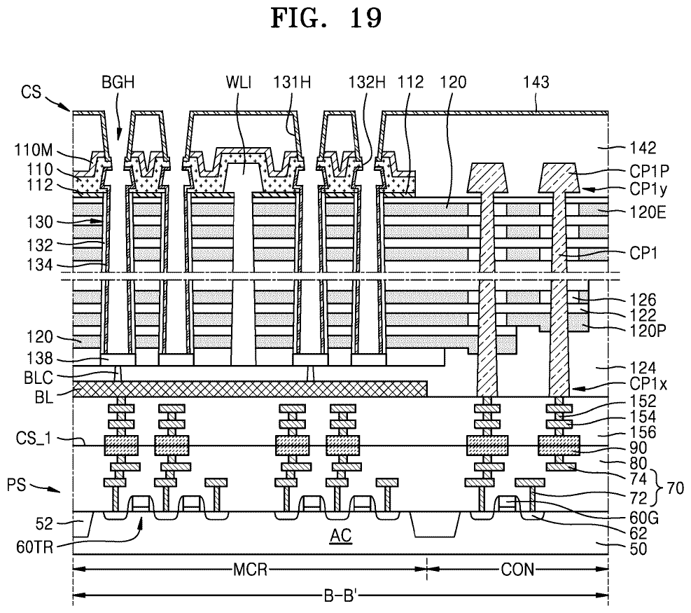

Referring to FIG. 19, the channel insulating layer 131P filling or in the channel hole 130H may be removed. By removing the channel insulating layer 131P filling or in the channel hole 130H, a back gate through hole BGH may be formed. As the back gate through hole BGH is formed, a top surface of the drain region 138 may be exposed. The channel insulating layer 131P exposed through the first back gate hole 131H and the second back gate hole 133H may be removed through an etching process. As the channel insulating layer 131P is removed, the sidewall of the channel layer 134 may be exposed.

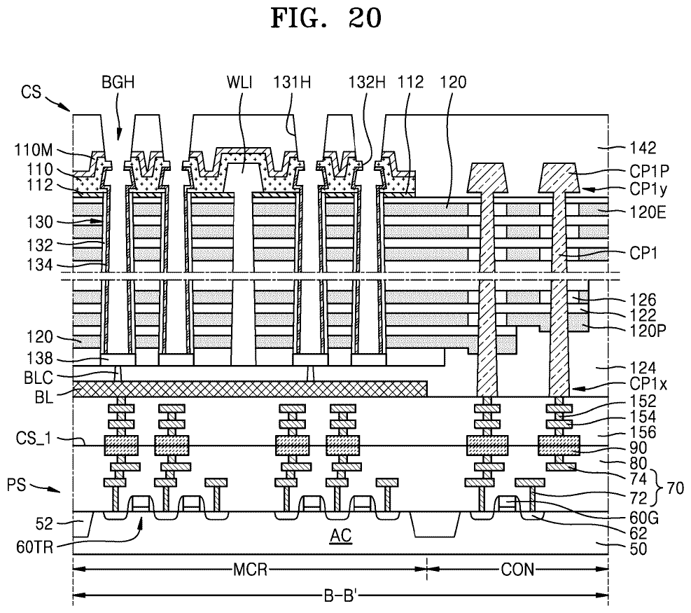

Referring to FIG. 20, the insulating spacer 143 covering or overlapping the sidewall of the first back gate hole 131H and the top surface of the upper insulating layer 142 may be removed. By removing the insulating spacer 143, the sidewall of the first back gate hole 131H and the top surface of the upper insulating layer 142 may be exposed again.

In some embodiments, the process of removing the insulating spacer 143 covering or overlapping the sidewall of the first back gate hole 131H and the top surface of the upper insulating layer 142 may be omitted. When the insulating spacer 143 is not removed, the semiconductor device 100 may be substantially the same as the semiconductor device 100B described with reference to FIGS. 8 and 9. Except for the process of removing the insulating spacer 143, the semiconductor device 100B described with reference to FIGS. 8 and 9 may be manufactured in substantially the same manner as the semiconductor device 100 described with reference to FIGS. 10 to 22.

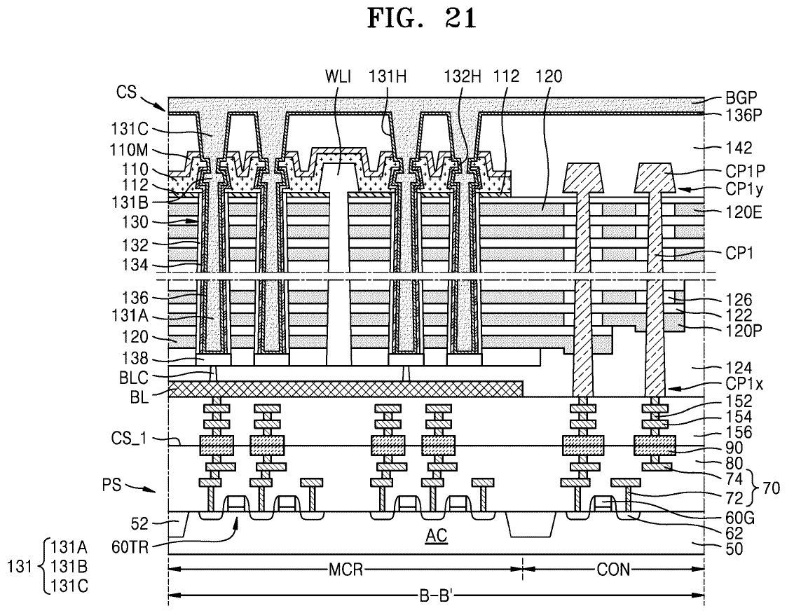

Referring to FIG. 21, a preliminary back gate insulating layer 136P and a preliminary back gate electrode BGP may be sequentially formed to fill or be in the back gate through hole BGH. The preliminary back gate insulating layer 136P may conformally cover or overlap an inner wall of the channel layer 134, an inner wall of the second back gate hole 132H, an inner wall of the first back gate hole 131H, and the top surface of the upper insulating layer 142. The preliminary back gate electrode BGP may conformally cover or overlap an inner wall and a top surface of the preliminary back gate insulating layer 136P.

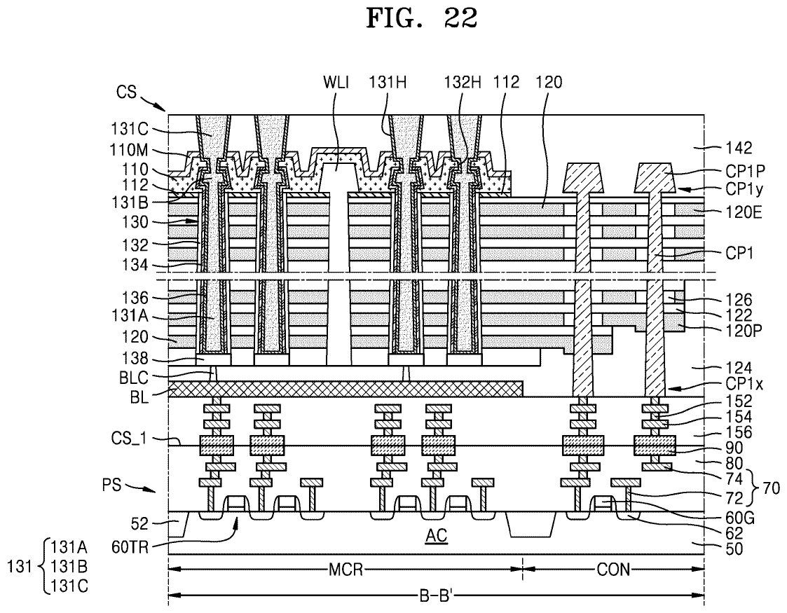

Referring to FIG. 22, portions of the preliminary back gate insulating layer 136P and the preliminary back gate electrode BGP may be removed, and the back gate insulating layer 136 and the back gate electrode 131 may be formed. The preliminary back gate insulating layer 136P, which covers or overlaps the upper insulating layer 142, and the preliminary back gate electrode BGP may be removed by a chemical mechanical polishing (CMP) process.

In some embodiments, the back gate insulating layer 136 arranged in the channel hole 130H and the back gate hole may be formed as a single body. In addition, the first portion 131A, the second portion 131B, and the third portion 131C of the back gate electrode 131 may include the same material. In addition, the first portion 131A, the second portion 131B, and the third portion 131C may be formed as a single body. Because the first portion 131A, the second portion 131B, and the third portion 131C are formed as a single body, an interface may not be formed between the first portion 131A, the second portion 131B, and the third portion 131C.

Thereafter, referring again to FIG. 6, the first rear wiring layer 164 and the second rear wiring layer 166 may be formed on the upper insulating layer 142. The first rear wiring layer 164 may be electrically connected to the back gate contact 144, and the second rear wiring layer 166 may be electrically connected to the common source contact 146. For example, the first rear wiring layer 164 and the second rear wiring layer 166 may be arranged apart from each other in the horizontal direction.

Thereafter, a passivation layer 168 covering or overlapping the first rear wiring layer 164 and the second rear wiring layer 166 may be formed on the upper insulating layer 142, and the opening OP may be formed in the passivation layer 168 to expose top surfaces of the first rear wiring layer 164 and the second rear wiring layer 166.

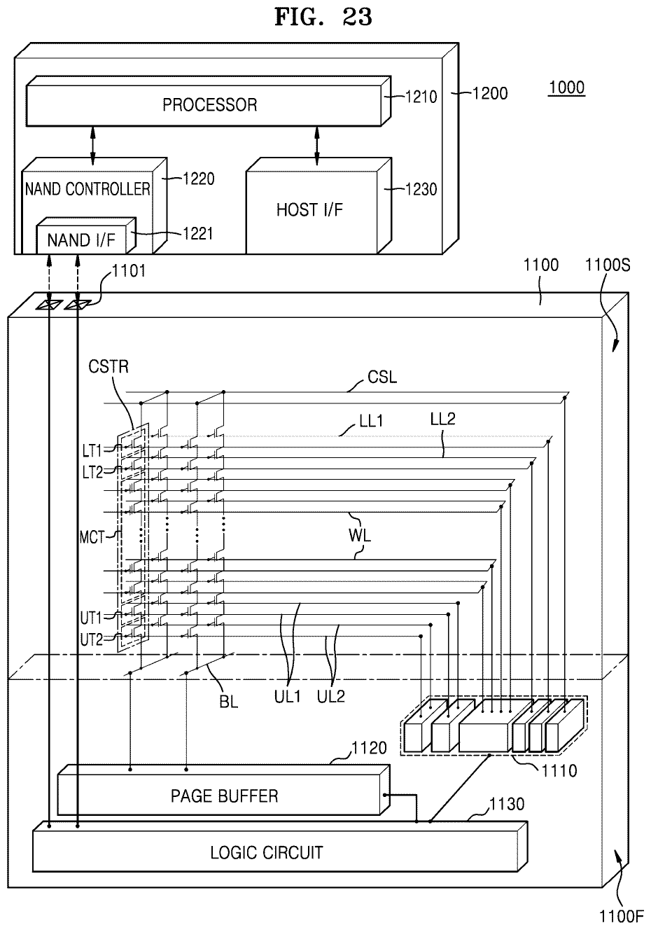

FIG. 23 is a schematic view of a data storage system 1000 including a semiconductor device according to embodiments.

Referring to FIG. 23, the data storage system 1000 may include at least one semiconductor device 1100 and a memory controller 1200 electrically connected to the semiconductor device 1100. For example, the data storage system 1000 may be a solid-state drive (SSD) device, a universal serial bus (USB), a computing system, a medical device, or a communication device, which includes at least one semiconductor device 1100.

The semiconductor device 1100 may be a non-volatile semiconductor device. For example, the semiconductor device 1100 may be a NAND flash semiconductor device including one of the semiconductor devices 10, 100, and 100B described with reference to FIGS. 1 to 9. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string select lines UL1 and UL2, first and second ground select lines LL1 and LL2, and a plurality of memory cell strings CSTR between the bit line BL and the common source line CSL.

In the second structure 1100S, each of the plurality of memory cell strings CSTR may include ground select transistors LT1 and LT2 adjacent to the common source line CSL, string select transistors UT1 and UT2 adjacent to the bit line BL, and a plurality of memory cell transistors MCT between the ground select transistors LT1 and LT2 and the string select transistors UT1 and UT2. The number of ground select transistors LT1 and LT2 and the number of string select transistors UT1 and UT2 may be variously modified according to embodiments.

In some embodiments, the first and second ground select lines LL1 and LL2 may be respectively connected to gate electrodes of the ground select transistors LT1 and LT2. The word line WL may be connected to a gate electrode of the memory cell transistor MCT. The first and second string select lines UL1 and UL2 may be respectively connected to gate electrodes of the string select transistors UT1 and UT2.

The common source line CSL, the first and second ground select lines LL1 and LL2, the plurality of word lines WL, and the first and second string select lines UL1 and UL2 may be connected to the row decoder 1110. A plurality of bit lines BL may be electrically connected to the page buffer 1120.

The semiconductor device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some embodiments, the data storage system 1000 may include a plurality of semiconductor devices 1100, and in this case, the memory controller 1200 may control the plurality of semiconductor devices 1100.

The processor 1210 may control overall operations of the data storage system 1000 including the memory controller 1200. The processor 1210 may operate according to certain firmware and may access the semiconductor device 1100 by controlling the NAND controller 1220. The NAND controller 1220 may include a NAND interface 1221 that processes communication with the semiconductor device 1100. Through the NAND interface 1221, a control command for controlling the semiconductor device 1100, data to be written to the plurality of memory cell transistors MCT of the semiconductor device 1100, data to be read from the plurality of memory cell transistors MCT of the semiconductor device 1100, etc., may be transmitted. The host interface 1230 may provide a communication function between the data storage system 1000 and an external host. When receiving a control command from the external host through the host interface 1230, the processor 1210 may control the semiconductor device 1100 in response to the control command.

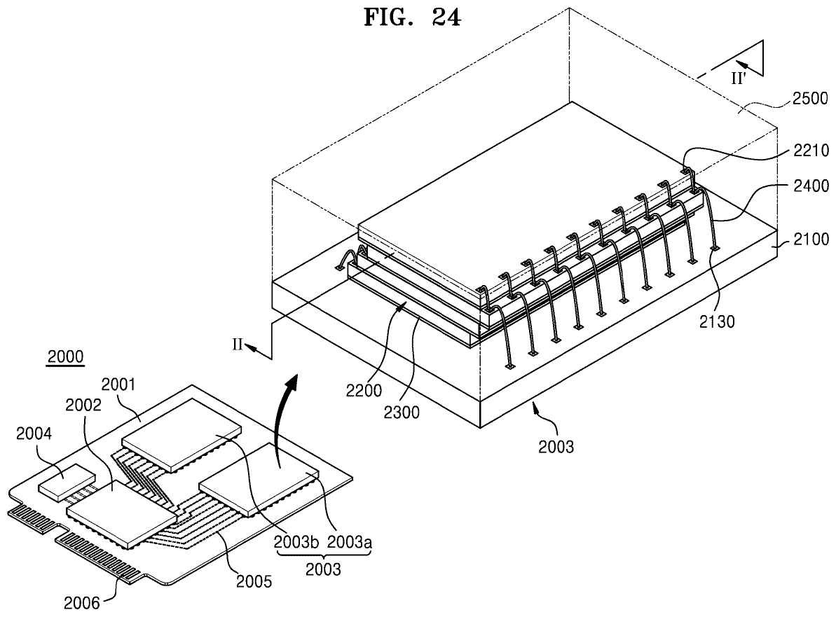

FIG. 24 is a schematic perspective view of a data storage system 2000 including a semiconductor device, according to embodiments.

Referring to FIG. 24, the data storage system 2000 according to an embodiment may include a main substrate 2001, a memory controller 2002 mounted on the main substrate 2001, at least one semiconductor package 2003, and a dynamic random-access memory (DRAM) 2004. The semiconductor package 2003 and the DRAM 2004 may be connected to the memory controller 2002 by a plurality of wiring patterns 2005 formed on the main substrate 2001.

The main substrate 2001 may include a connector 2006 including a plurality of pins coupled to an external host. The number and arrangement of the plurality of pins in the connector 2006 may vary according to a communication interface between the data storage system 2000 and the external host. In some embodiments, the data storage system 2000 may communicate with the external host according to any one of interfaces such as USB, peripheral component interconnect express (PCI-Express), serial advanced technology attachment (SATA), and M-Phy for universal flash storage (UFS). In some embodiments, the data storage system 2000 may operate by power supplied from the external host through the connector 2006. The data storage system 2000 may further include a power management integrated circuit (PMIC) that distributes the power supplied from the external host to the memory controller 2002 and the semiconductor package 2003.

The memory controller 2002 may write data to or read data from the semiconductor package 2003 and may improve an operation speed of the data storage system 2000.

The DRAM 2004 may be a buffer memory for reducing a speed difference between the semiconductor package 2003, which is a data storage space, and the external host. The DRAM 2004 included in the data storage system 2000 may operate as a kind of cache memory and may provide a space for temporarily storing data in a control operation on the semiconductor package 2003. When the DRAM 2004 is included in the data storage system 2000, the memory controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a bottom surface of each of the plurality of semiconductor chips 2200, a connection structure 2400 electrically connecting the plurality of semiconductor chips 2200 to the package substrate 2100, and a molding layer 2500 covering or overlapping the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 23. Each of the plurality of semiconductor chips 2200 may include at least one of the semiconductor devices 10, 100, and 100B described with reference to FIGS. 1 to 9.

In some embodiments, the connection structure 2400 may be a bonding wire electrically connecting the input/output pad 2210 to the package upper pad 2130. Accordingly, in the first and second semiconductor packages 2003a and 2003b, the plurality of semiconductor chips 2200 may be electrically connected to each other by a bonding wire method and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including a through silicon via (TSV) instead of the connection structure 2400 of the bonding wire type.

In some embodiments, the memory controller 2002 and the plurality of semiconductor chips 2200 may be included in one package. In some embodiments, the memory controller 2002 and the plurality of semiconductor chips 2200 may be mounted on a separate interposer substrate that is different from the main substrate 2001, and may be connected to each other by a wiring formed on the interposer substrate.

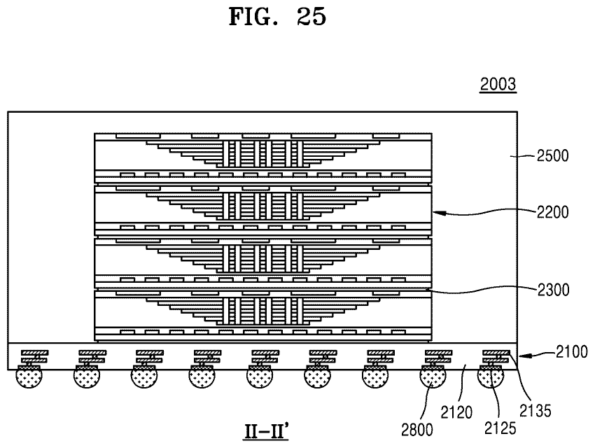

FIG. 25 is a schematic cross-sectional view of the semiconductor package 2003 according to embodiments. FIG. 25 is a cross-sectional view of the semiconductor package 2003, taken along line II-II′ of FIG. 24.

Referring to FIG. 25, in the semiconductor package 2003, the package substrate 2100 may be a printed circuit board. The package substrate 2100 may include a package substrate body 2120, the plurality of package upper pads 2130 (see FIG. 24) arranged on a top surface of the package substrate body 2120, a plurality of lower pads 2125 arranged on or exposed through a bottom surface of the package substrate body 2120, and a plurality of internal wirings 2135 electrically connecting the plurality of package upper pads 2130 (see FIG. 24) to the plurality of lower pads 2125 in the package substrate body 2120. As shown in FIG. 24, the plurality of package upper pads 2130 may be electrically connected to a plurality of connection structures 2400. As shown in FIG. 25, the plurality of lower pads 2125 may be connected to the plurality of wiring patterns 2005 on the main substrate 2001 of the data storage system 2000, which is shown in FIG. 24, through a plurality of conductive bumps 2800. Each of the plurality of semiconductor chips 2200 may include at least one of the semiconductor devices 10, 100, and 100B described with reference to FIGS. 1 to 9.

While the present disclosure has been particularly shown and described with reference to embodiments thereof, it will be understood that various changes in form and details may be made therein without departing from the spirit and scope of the following claims.

What is claimed is:

1. A semiconductor device comprising:
a peripheral circuit structure; and
a cell structure on the peripheral circuit structure,
wherein the cell structure comprises:
gate electrodes extending in a first direction and spaced apart from each other in a second direction intersecting the first direction, wherein the gate electrodes define a channel hole extending in the second direction;
a channel layer comprising a first region in the channel hole and a second region extending from the first region in the second direction;
a common source layer electrically connected to the second region of the channel layer;
an upper insulating layer on the common source layer, wherein the upper insulating layer, the common source layer, and the second region of the channel layer define a back gate hole extending in the second direction;
a back gate insulating layer on inner walls of the channel hole and inner walls of the back gate hole and extending in the second direction; and
a back gate electrode that is in the channel hole and the back gate hole and is on the back gate insulating layer.

2. The semiconductor device of claim 1, further comprising:
a back gate contact extending into the upper insulating layer and electrically connected to the back gate electrode; and
a common source contact extending into the upper insulating layer and electrically connected to the common source layer.

3. The semiconductor device of claim 1, wherein the back gate electrode comprises:
a first portion on the first region of the channel layer;
a second portion electrically connected to the first portion and on the second region of the channel layer; and
a third portion electrically connected to the second portion and in the back gate hole.

4. The semiconductor device of claim 3, wherein the first portion, the second portion, and the third portion of the back gate electrode comprise a same material and are unitary.

5. The semiconductor device of claim 3, wherein the back gate hole comprises:
a first back gate hole defined by a portion of the upper insulating layer and a first portion of the common source layer; and
a second back gate hole defined by a second portion of the common source layer and the second region of the channel layer,
wherein a width of the third portion of the back gate electrode in the first back gate hole in the first direction is greater than a width of the second portion of the back gate electrode in the second back gate hole in the first direction.

6. The semiconductor device of claim 5, wherein the common source layer comprises a protrusion extending toward the second back gate hole in the first direction.

7. The semiconductor device of claim 3, wherein a width of the third portion of the back gate electrode in the first direction increases as the third portion of the back gate electrode extends from the peripheral circuit structure in the second direction.

8. The semiconductor device of claim 1, wherein the back gate insulating layer is on inner walls of the first region of the channel layer and inner walls of the second region of the channel layer.

9. The semiconductor device of claim 1, wherein a width of the second region of the channel layer in the first direction is greater than a width of the first region of the channel layer in the first direction.

10. The semiconductor device of claim 1, further comprising an upper conductive layer between the common source layer and the upper insulating layer.

11. A semiconductor device comprising:
a peripheral circuit structure; and
a cell structure on the peripheral circuit structure,
wherein the cell structure comprises:
gate electrodes extending in a first direction and spaced apart from each other in a second direction intersecting the first direction, wherein the gate electrodes define a channel hole extending in the second direction;
a channel layer comprising a first region in the channel hole and a second region extending from the first region in the second direction;
a common source layer electrically connected to the second region of the channel layer;
an upper insulating layer on the common source layer, wherein the upper insulating layer, the common source layer, and the second region of the channel layer define a back gate hole comprising a first back gate hole and a second back gate hole, the first back gate hole defined by a portion of the upper insulating layer and a first portion of the common source layer, and the second back gate hole defined by a second portion of the common source layer and the second region of the channel layer;
a back gate insulating layer on inner walls of the channel hole and inner walls of the back gate hole and extending in the second direction;
a back gate electrode that is in the channel hole and the back gate hole and is on the back gate insulating layer; and
an insulating spacer on inner walls of the first back gate hole.

12. The semiconductor device of claim 11, further comprising:
a back gate contact extending into the upper insulating layer and electrically connected to the back gate electrode; and
a common source contact extending into the upper insulating layer and electrically connected to the common source layer.

13. The semiconductor device of claim 11, wherein the back gate electrode comprises:
a first portion on the first region of the channel layer;
a second portion electrically connected to the first portion of the back gate electrode and on the second region of the channel layer; and
a third portion electrically connected to the second portion of the back gate electrode and in the back gate hole,
wherein the first portion, the second portion, and the third portion comprise a same material and are unitary.

14. The semiconductor device of claim 11, wherein the insulating spacer is on a bottom surface of the first back gate hole.

15. The semiconductor device of claim 11, wherein a width of the first back gate hole in the first direction is greater than a width of the second back gate hole in the first direction.

16. The semiconductor device of claim 11, wherein the common source layer comprises a protrusion extending toward the second back gate hole in the first direction.

17. The semiconductor device of claim 11, further comprising an upper conductive layer between the common source layer and the upper insulating layer.

18. A semiconductor device comprising:
a peripheral circuit structure; and
a cell structure on the peripheral circuit structure,
wherein the cell structure comprises:
gate electrodes extending in a first direction and spaced apart from each other in a second direction intersecting the first direction, wherein the gate electrodes define a channel hole extending in the second direction;
a channel structure comprising a back gate insulating layer, a back gate electrode, and a channel layer between the back gate insulating layer and the back gate electrode, the channel layer comprising a first region in the channel hole and a second region extending from the first region in the second direction;
a common source layer electrically connected to the second region of the channel layer;
an upper conductive layer on the common source layer;
an upper insulating layer on the upper conductive layer, wherein the upper insulating layer, the common source layer, and the second region of the channel layer define a back gate hole comprising a first back gate hole and a second back gate hole, the first back gate hole defined by a portion of the upper insulating layer, a portion of the upper conductive layer, and a first portion of the common source layer, and the second back gate hole defined by a second portion of the common source layer and the second region of the channel layer;
a back gate contact extending into the upper insulating layer and electrically connected to the back gate electrode; and
a common source contact extending into the upper insulating layer and electrically connected to the common source layer,
wherein the back gate insulating layer extends in the second direction and is on an inner wall of the back gate hole, and
wherein the back gate electrode extends in the second direction, is on the back gate insulating layer, and is in the back gate hole.

19. The semiconductor device of claim 18, further comprising an insulating spacer on an inner wall of the first back gate hole.

20. The semiconductor device of claim 18, wherein the common source layer comprises a protrusion extending toward the second back gate hole in the first direction.
